(19) United States
(12) Patent Application Publication
(10) Pub. No.: US 2012/0160419 A1
(43) Pub. Date: Jun. 28, 2012

(54) SUBSTRATE-SUPPORTING UNIT AND SUBSTRATE-PROCESSING APPARATUS COMPRISING SAME

(76) Inventors: Dong-Keun Lee, Chungheongnam-do (KR); Sergey Zaretskiy, Gyeonggi-do (LR); Sung Tae Je, Gyeonggi-do (KR); Wan Suk Oh, Gyeonggi-do (KR)

(21) Appl. No.: 13/375,403

(22) PCT Filed: Apr. 12, 2010
(86) PCT No.: PCT/KR2010/002227

§ 371 Date: Nov. 30, 2011

(51) Int. Cl. B05C 13/02; H01L 21/683; B23Q 3/00; C23C 16/46

(52) U.S. Cl. 156/345.52; 118/725; 269/289 R; 269/296

(57) ABSTRACT

A substrate-supporting unit includes: a mounting board on which a substrate is disposed; and a heater installed in the mounting board to heat the substrate disposed on the mounting board, wherein the mounting board includes: a non-contact surface which faces a center portion of the substrate and is spaced apart from the center portion of the substrate; and a contact member which extends outward from the non-contact surface and is arranged along an edge portion of the substrate disposed on the mounting board to support the edge portion of the substrate.

### TECHNICAL FIELD

The present invention disclosed herein relates to a substrate-supporting unit and substrate-treating apparatus, and more particularly, to a substrate-supporting unit provided with a non-contact surface, and a substrate-treating apparatus including the same.

### BACKGROUND ART

A method for manufacturing a semiconductor device using a heater is typically used in a single wafer chemical vapor deposition and in a chemical vapor deposition using plasma.

In a conventional substrate-supporting method, a substrate partially or fully contacts an upper surface of a mounting board when the substrate is mounted on the upper surface of the mounting board. The substrate is mounted on the mounting board at room temperature and the mounting board installed in a reaction chamber of a high temperature maintains a high temperature above room temperature. Therefore, when the substrate is mounted on the mounting board, the substrate is heated through heat exchange with the mounting board, resulting in heat expansion in the substrate.

Thus, in the case the substrate is thermally expanded, a substrate sliding occurs due to the mounting board partially or fully contacting the substrate. In the case the substrate is thermally expanded and a portion expanded thermally in the substrate is limited due to the mounting board, the substrate slides so as to secure an expansion space. This substrate sliding causes a limitation in the process uniformity.

### DISCLOSURE

Technical Problem

The present invention provides a substrate-supporting unit that can prevent substrate sliding, and a substrate-treating apparatus including the same.

The present invention also provides a substrate-supporting unit that can secure process uniformity with respect to a substrate, and a substrate-treating apparatus including the same.

Technical Solution

According to the present invention, a substrate-supporting unit includes: a mounting board on which a substrate is disposed; and a heater installed in the mounting board to heat the substrate disposed on the mounting board, wherein the mounting board includes: a non-contact surface which faces a center portion of the substrate and is spaced apart from the center portion of the substrate; and a contact member which extends outward from the non-contact surface and is arranged along an edge portion of the substrate disposed on the mounting board to support the edge portion of the substrate.

The contact member may be disposed protrudedly from the non-contact surface.

The contact member may have a plurality of supporting members arranged along the edge portion of the substrate.

The contact member may have a ring shape disposed along the edge portion of the substrate.

The mounting board may further include a guide ring which is disposed outside the contact member to guide the substrate, and the guide ring may have a guide surface inclined toward an inner side of the mounting board.

The mounting board may further include a protruding member which is installed to protrude from the non-contact surface and is spaced apart from the substrate to adjust a spacing from the substrate.

According to the present invention, a substrate-treating apparatus includes: a chamber providing a process space for a substrate; a mounting board which is installed in the process space and on which a substrate is disposed; and a heater installed in the mounting board to heat the substrate disposed on the mounting board, wherein the mounting board includes: a non-contact surface which faces a center portion of the substrate and is spaced apart from the center portion of the substrate; and a contact member which extends outward from the non-contact surface and is arranged along an edge portion of the substrate disposed on the mounting board to support the edge portion of the substrate.

### ADVANTAGEOUS EFFECTS

According to the embodiments of the present invention, sliding of the substrate can be prevented. Also, the process uniformity for the substrate can be secured.

### DESCRIPTION OF DRAWINGS

FIG. 1 is a view schematically illustrating a substrate-treating apparatus according to an embodiment of the present invention.

FIG. 2 is a view illustrating a substrate-supporting unit illustrated in FIG. 1.

FIG. 3 is a view illustrating a substrate-supporting unit according to another embodiment of the present invention.

FIG. 4 is a graph showing a process result obtained by using a conventional substrate-supporting unit.

FIG. 5 is a graph showing a process result obtained by using a substrate-supporting unit according to an embodiment of the present invention.

### BEST MODE

Preferred embodiments of the present invention will be described below in more detail with reference to the accompanying drawings. The present invention may, however, be embodied in different forms and should not be constructed as limited to the embodiments set forth herein. Rather, these embodiments are provided so that this disclosure will be thorough and complete, and will fully convey the scope of the present invention to those skilled in the art. In the drawings, the dimensions of elements are exaggerated for clarity of illustration.

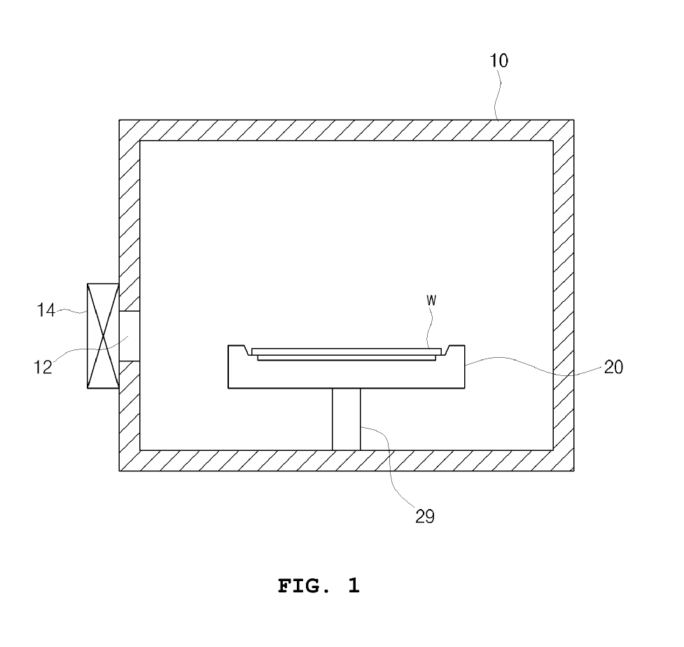

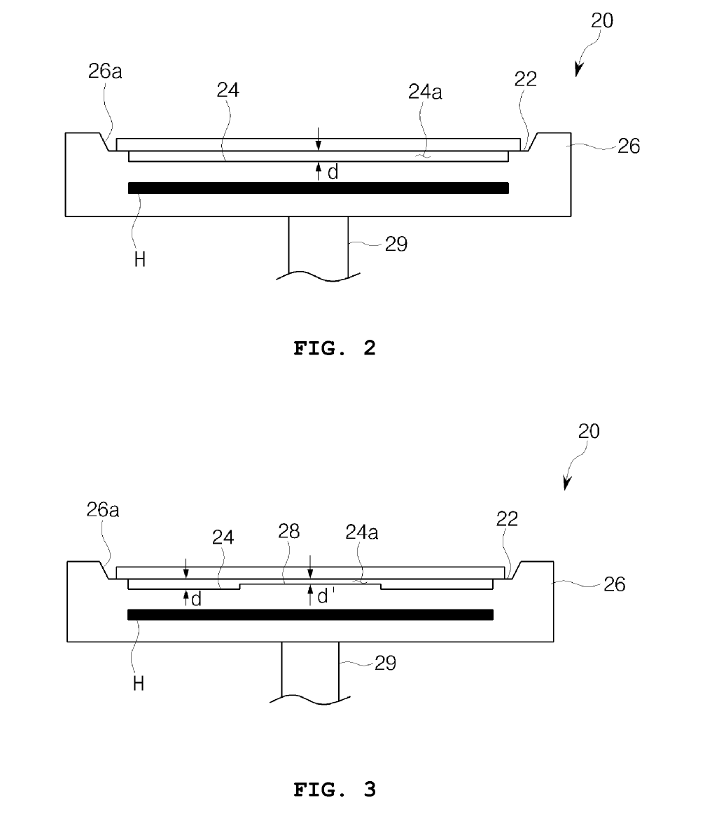

FIG. 1 is a view schematically illustrating a substrate-treating apparatus according to an embodiment of the present invention, and FIG. 2 is a view illustrating a substrate-supporting unit illustrated in FIG. 1.

As illustrated in FIG. 1, a substrate-treating apparatus includes a chamber 10, and a substrate-supporting unit 20 installed in the chamber 10. The chamber 10 provides an inner space shielded from the outside, and a process for a substrate (W) is performed in the inner space. Besides deposition and etching, various semiconductor manufacturing processes for the substrate (W) may be performed in the chamber.

The chamber 10 has a gate 12 formed in one side thereof, and the substrate (W) is loaded into the inside of the chamber 10 or unloaded to the outside from the chamber 10 through the gate 12. A gate valve 14 is installed in the outside of the gate 12 to open or close the gate 12.

Meanwhile, the substrate-supporting unit 20 is installed in the chamber 10, and supports the substrate (W) loaded through the gate 12. The substrate-supporting unit 20 includes a mounting board and a supporting shaft 29, and the supporting shaft 29 may move the mounting board upward and downward according to the process progress.

As illustrated in FIG. 2, the mounting board includes a contact member 22, a non-contact surface 24, and a guide ring 26. The non-contact surface 24 is depressed and is thus leveled lower than the upper surface of the contact member 22, and the contact member 22 is protruded from the non-contact surface 24 and thus is the upper surface of the contact member 22 is leveled higher than the non-contact surface 24. A height difference between the upper surface of the contact member 22 and the non-contact surface 24 is in the range of approximately 1 μm to approximately 100 μm.

The non-contact surface 24 has a shape (e.g., circular or rectangular form) generally corresponding to the shape of the substrate (W), but may have a shape different from the shape of the substrate (W). The non-contact surface 24 is positioned under a center portion of the substrate (W) disposed on the mounting board.

The contact member 22 is disposed outside the non-contact surface 24, and the substrate (W) is disposed on the upper surface of the contact member 22. The contact member 22 supports an edge portion of the substrate (W) disposed thereon, and is disposed along the edge portion of the substrate (W). The edge portion may have a length ranging from approximately 1 mm to approximately 30 mm as measured in the radial direction.

The contact member 22 may include a plurality of supporting members having a ring or arc shape.

In the case the substrate (W) is mounted on the contact member 22, the non-contact surface 24, which is depressed from the contact member 22, is spaced apart by a distance (=d) from the substrate (W), and a fluidic space 24a is formed.

Also, the mounting board further includes a heater (H), which heats the substrate (W) mounted on the contact member 22. Meanwhile, the mounting board may be a heater type including the heater (H), or a susceptor type in which a structure having another shape is coupled to a heater. That is, the mounting board described in this embodiment indicates a structure capable of mounting the substrate (e.g., a wafer or plat panel for display), and is used as the term encompassing the heater type and the susceptor type.

In the case the substrate (W) is heated by the heater (H), the substrate (W) is thermally deformed due to thermal expansion, so that deflection of the substrate (W) occurs at the center portion of the substrate (W). At this time, the fluidic space 24a provides a space which the center of the substrate (W) may move. That is, the substrate (W) maintains a status supported by the contact member 22, and the center of the substrate (W) is deflected toward the non-contact surface 24 in the fluidic space 24a.

If the fluidic space 24a is not provided, i.e., if the substrate (W) fully contacts the mounting board, the thermal expansion (or deflection) of the substrate (W) is limited by the mounting board, so that the substrate (W) slides from the upper surface of the mounting board and thus is eccentrically mounted. Especially, since the thermal deformation of the substrate (W) is proportional to the size of the substrate (W), as the size of the substrate increases, the eccentric amount of the substrate (W) increases. However, in the case the fluidic space 24a is provided, the thermal deformation (or deflection) of the substrate (W) is not limited, so that the sliding of the substrate (W) due to the thermal deformation can be prevented.

Meanwhile, the spacing distance (d) between the non-contact surface 24 and the substrate (W) should be adjusted such that the thermal deformation of the substrate (W) is not limited by the non-contact surface 24, and the spacing distance (d) may be proportional to the thermal deformation amount of the substrate (W).

The mounting board further includes a guide ring 26 disposed outside the contact member 22, and the guide ring 26 has a shape generally corresponding to the shape of the substrate (W). The guide ring 26 has a guide surface 26a inwardly inclined toward the center of the mounting board, and the substrate (W) on the mounting board may be safely mounted at a preset position on the mounting board along the guide surface 26a of the guide ring 26.

FIG. 3 is a view illustrating a substrate-supporting unit according to another embodiment of the present invention. As illustrated in FIG. 3, a substrate-supporting unit 20 further includes a protruding member 28 installed on a non-contact surface 24. The protruding member 28 is disposed spaced apart by a distance (=d′) from the substrate (W), and a fluidic space 24a is defined between the protruding member 28 and the substrate (W).

Heat generated from the heater (H) is transferred to the non-contact surface 24 and the protruding member 28, and is then transferred to the substrate (W) through convection or the like. At this time, since the distance (d) between the non-contact surface 24 and the substrate (W) is greater than the distance (d′) between the protruding member 28 and the substrate (W), the thermal transfer amount of the protruding member 28 per unit area is greater than that of the non-contact surface 24 per unit area.

By using the above principle, it is possible to compensate for the temperature gradient generated on the substrate (W) heated by the heater (H). That is, in the case the protruding member 28 is formed on a low temperature region in the entire region of the substrate (W) heated by the heater (H), the temperature gradient of the corresponding region may be removed, and the temperature uniformity and process uniformity may be secured.

As described previously, in the case the substrate (W) is heated by the heater (H), the substrate (W) maintains the status supported by the contact member 22, and the center portion of the substrate (W) is deflected toward the non-contact surface within the fluidic space 24a. The spacing distance (d′) between the protruding member 28 and the substrate (W) should be adjusted such that the thermal deformation of the substrate (W) is not limited by the protruding member 28, and the spacing distance (d) may be proportional to the thermal deformation amount of the substrate (W).

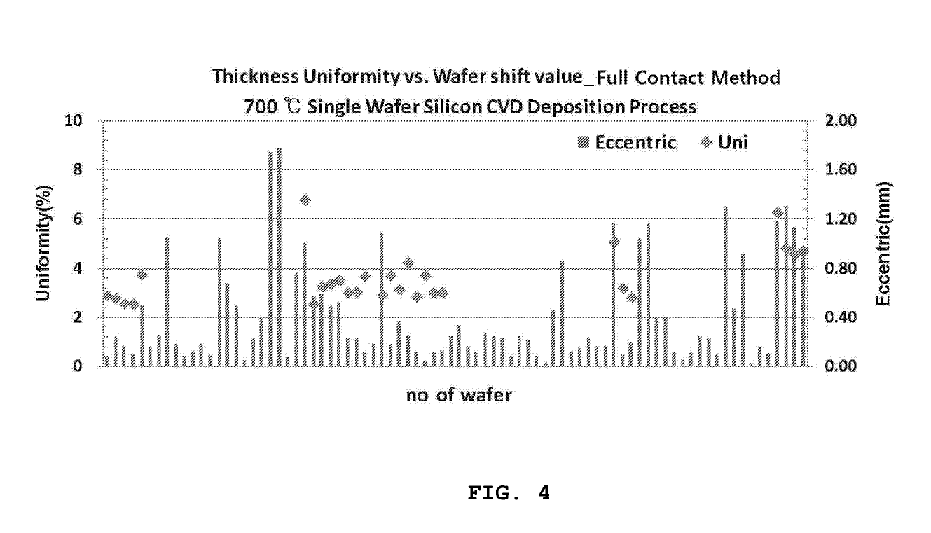

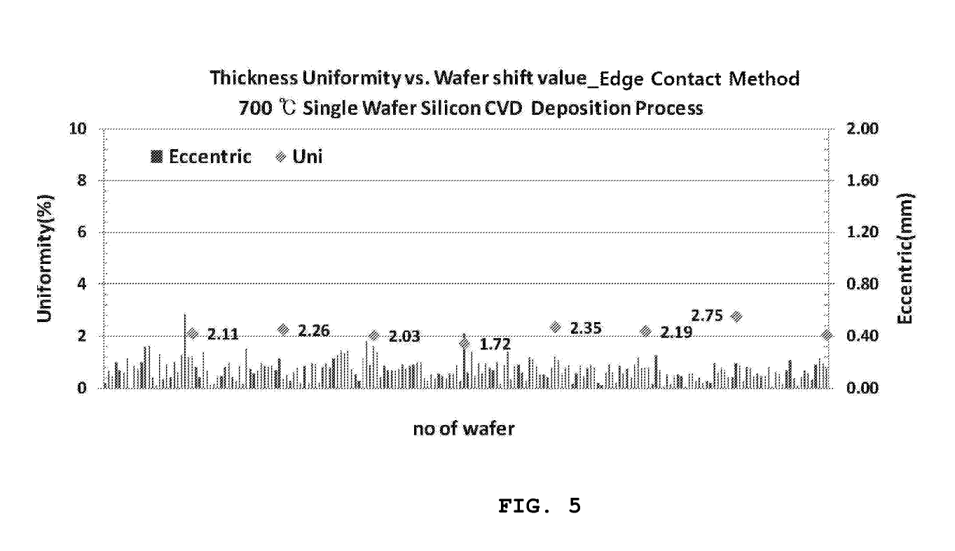

FIG. 4 is a graph showing a process result obtained by using a conventional substrate-supporting unit, and FIG. 5 is a graph showing a process result obtained by using a substrate-supporting unit according to an embodiment of the present invention.

As illustrated in FIG. 4, when the conventional substrate-supporting unit employing the full contact method was used, the eccentric amount of the substrate (W) was in the range of approximately 0.05 mm to approximately 1.80 mm, and the process uniformity of the substrate (W) was in the range of approximately 2.4% to approximately 6.8%.

On the other hand, as illustrated in FIG. 5, when the substrate-supporting unit employing the partial contact method was used, the eccentric amount of the substrate (W) was in the range of approximately 0.05 mm to approximately 0.6 mm, and the process uniformity of the substrate (W) was in the range of approximately 1.72% to approximately 2.75%. That is, it can be seen that the edge portion contact method improves the eccentric amount and the process uniformity greatly.

While this invention has been described in detail with reference to preferred embodiments thereof, it will be understood by those skilled in the art that various changes in form and details may be made therein. Thus, the technical spirit and scope of the following claims shall not be restricted or limited by the foregoing preferred embodiments.

What is claimed is:

1. A substrate-supporting unit comprising:
a mounting board on which a substrate is disposed; and
a heater installed in the mounting board to heat the substrate disposed on the mounting board,
wherein the mounting board includes: a non-contact surface which faces a center portion of the substrate and is spaced apart from the center portion of the substrate; and
a contact member which extends outward from the non-contact surface and is arranged along an edge portion of the substrate disposed on the mounting board to support the edge portion of the substrate.

2. The substrate-supporting unit of claim 1, wherein the contact member is disposed protrudedly from the non-contact surface.

3. The substrate-supporting unit of claim 1, wherein the contact member has a plurality of supporting members arranged along the edge portion of the substrate.

4. The substrate-supporting unit of claim 1, wherein the contact member has a ring shape disposed along the edge portion of the substrate.

5. The substrate-supporting unit of claim 1, wherein the mounting board further comprises a guide ring which is disposed outside the contact member to guide the substrate, wherein the guide ring has a guide surface inclined toward an inner side of the mounting board.

6. The substrate-supporting unit of claim 1, wherein the mounting board further comprise a protruding member which is installed to protrude from the non-contact surface and is spaced apart from the substrate to adjust a spacing from the substrate.

7. The substrate-supporting unit of claim 1, wherein a height difference between an upper surface of the contact member and the non-contact surface is in a range of 1 μm to 100 μm.

8. The substrate-supporting unit of claim 1, wherein the edge portion has a length of 1 mm to 30 mm as measured in the radial direction of the substrate.

9. A substrate-treating apparatus comprising:
a chamber providing a process space for a substrate;
a mounting board which is installed in the process space and on which a substrate is disposed; and
a heater installed in the mounting board to heat the substrate disposed on the mounting board,
wherein the mounting board includes: a non-contact surface which faces a center portion of the substrate and is spaced apart from the center portion of the substrate; and
a contact member which extends outward from the non-contact surface and is arranged along an edge portion of the substrate disposed on the mounting board to support the edge portion of the substrate.
